(19) United States
(12) Patent Application Publication
(10) Pub. No.: US 2005/0191421 A1
(43) Pub. Date: Sep. 1, 2005

(54) Method for coating a component

(76) Inventors: Thomas Berndt, Berlin (DE); Nigel-Philip Cox, Berlin (DE); Andreas Griep, Ahrensfelde (DE); Guido Kern, Berlin (DE); Gerhard Reich, Berlin (DE); Ralph Reiche, Berlin (DE)

Correspondence Address: SIEMENS CORPORATION;INTELLECTUAL PROPERTY DEPT., 170 WOOD AVENUE SOUTH, ISELIN, NJ, 08830, US

(21) Appl. No.: 10/667,266

(22) Filed: Sep. 19, 2003

(30) Foreign Application Priority Data
Apr. 10, 2002 (EP) 02008044.6 EP
Mar. 21, 2003 (WO) PCT/EP03/02977

(51) Int. Cl. C23C 16/00; B05D 1/32

(52) U.S. Cl. 427/282; 427/250; 427/255.28

(57) ABSTRACT

Coatings that are applied to a component have to be removed again from certain areas using costly methods, because coating was not required in those areas. The subsequent removal of this layer can impair the component, for example in terms of its geometry. The inventive method for coating a component uses a mask, which consists at least partially of a ceramic powder and can therefore easily be removed after the component has been coated.

The invention relates to a method for coating a component in accordance with the preamble of Claim 1.

When components are coated, parts of the outer or inner surface of the component sometimes have to be left uncoated. This applies for all coating processes, e.g. plasma spray, PVD (physical vapor deposition) or CVD (chemical vapor deposition) processes.

Parts of the coating have to be removed in the areas where coating was not required. This is often done by abrasive removal of the coating in these areas, since the material used for the coating adheres very firmly to the component or even reacts with it, for example if the component was coated with aluminum in order to alitize it.

Abrasive removal can however damage the component or alter its geometry. This is the case, for example, with sand blasting, in which sand particles are used to remove the aluminum from the component again.

U.S. Pat. No. 6,036,995 demonstrates the necessity of masking using adhesive tapes or metal foils. The coating is carried out by applying slurry. Metal foils do not adhere well to a substrate and thus provide inadequate protection in a vaporization system, in which the particles to be applied are moving in all directions. Adhesive tapes do not withstand high temperatures.

In U.S. Pat. No. 5,985,368, a coating is applied using a ceramic slurry. There is no masking.

U.S. Pat. No. 6,283,714 demonstrates the necessity of masking when coating with aluminum. However, a certain arrangement within the coating system prevents aluminum from being deposited in the places where it is not required.

The purpose of the invention is therefore to provide a method for coating a component, in which a mask is used to prevent coating being applied to the areas where it is not required, and in which the said mask can be easily removed.

The object is achieved by means of a method according to Claim 1, in which the surface of the areas in which coating is not required is at least partially protected by a ceramic powder.

Further enhancements to the method in accordance with Claim 1 are listed in the subclaims.

Exemplary embodiments are explained in the subsequent diagrams.

In these,

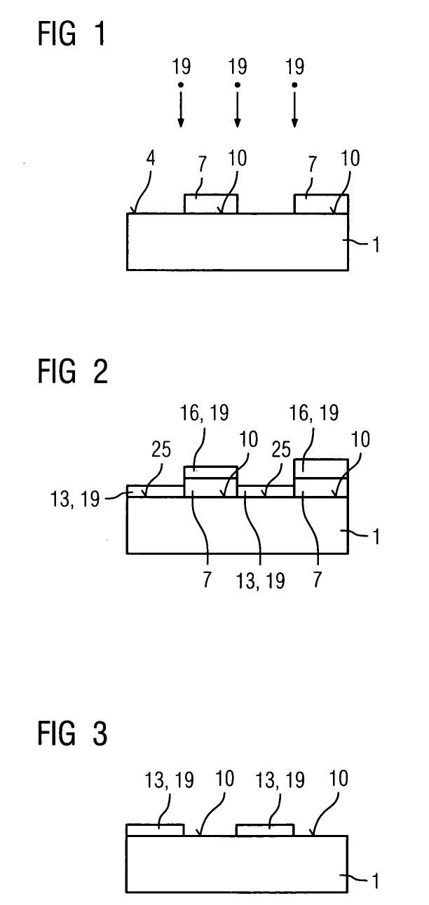

FIGS. 1, 2 and 3 show the method steps according to the inventive method, and

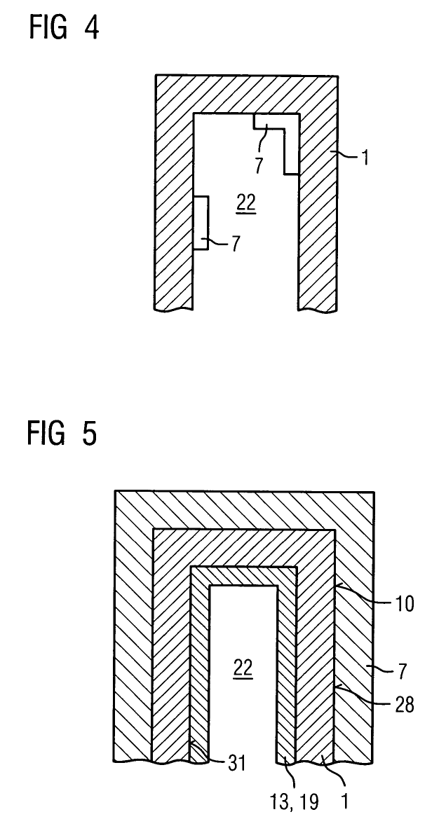

FIGS. 4 and 5 show further exemplary embodiments for the application of the inventive method.

FIG. 1 shows a component 1, in particular a turbine blade of a gas turbine, for example consisting of a nickel-based or cobalt-based superalloy, which has a surface 4.

The surface 4 of the component 1 is to be coated with a ceramic or metallic coating material 19, such as aluminum, for example.

The component has areas 10 that are not required to be coated with the coating material 19, for example a blade root (fastening area) of a turbine blade.

These areas 10 are protected by a mask 7. The mask 7 consists of a suspension, a slurry or a paste of a ceramic powder, in particular zirconium oxide, which is applied to the component 1 by dipping the component in the suspension, or by brush-painting, spraying, or other method of application. The application may be performed locally or over a larger area. The mask 7 does not react with the component 1. The mask 7 continues to adhere to the component 1 while the component 1 is being coated, for example due to the presence of an organic binding agent in the paste or suspension.

The component 1 is coated with the coating material 19 by means of a CVD (chemical vapor deposition) process, PVD (plasma vapor deposition) process, or plasma spraying. Further coating methods are possible.

FIG. 2 shows the component 1, which has been coated. The component 1 has areas 25 with a coating 13 on the surface 4, where this is required. There is also a coating 16 on the mask 7.

Since the mask 7 can easily be removed because, for example, it only adheres to the component 1 because of the organic binding agent, this means that there is also no impairment of the component 1 in the areas 10 in which coating was not required (FIG. 3).

The mask 7 may, for example, be removed by washing off or by dry ice blasting.

FIG. 4 shows a further application example for the inventive method.

The component 1 may also have a cavity 22, in which a mask 7 is applied. The method is therefore also suitable for outer and inner surfaces.

FIG. 5 shows a further application example for the inventive method.

In the component 1, a coating 13 is applied in the cavity 22 of the component 1.

Coating is not required for the outer surface 28 of the component 1, and so a mask 7 is applied to the outer surface 28 of the component 1. In this way the entire component 1 with the mask 7 can be introduced into the coating process with the coating being applied only to the required areas on the inner surface 31 of the component 1, and not to the area 10 in which coating is not required. The inner surface 31 can likewise be partially protected by a mask. This is particularly useful, for example, when carrying out the internal alitization of turbine blades for a gas turbine.

1-6. (canceled)

7. A method for coating a surface of a component, comprising:
applying a mask having a layer of ceramic powder to an uncoated area of the surface of the component; and
coating of the component,
whereby no binding agent is used to produce the mask layer.

8. A method according to claim 7, wherein the mask is formed from a suspension with the ceramic powder.

9. A method according to claim 7, wherein the mask is formed from a paste with a ceramic powder.

10. A method according to claim 7, wherein the ceramic powder comprises a zirconium oxide powder.

11. A method according to claim 7, wherein an aluminum layer is applied to the component.

12. A method according to claim 7, wherein the coating is applied by a chemical vapor deposition process.

13. A method according to claim 7, wherein the component is a part of a turbine.

14. A method according to claim 13, wherein the part of the turbine is a turbine blade.

15. A method for coating a surface of a component, comprising:
applying a mask having a layer of ceramic powder to an uncoated area of the surface of the component; and
coating of the component.

16. A method according to claim 15, wherein the mask is formed from a suspension with the ceramic powder.

17. A method according to claim 15, wherein the mask is formed from a paste with a ceramic powder.

18. A method according to claim 15, wherein the ceramic powder comprises a zirconium oxide powder.

19. A method according to claim 15, wherein an aluminum layer is applied to the component.

20. A method according to claim 15, wherein the coating is applied by means of a chemical vapor deposition process.

21. A method according to claim 15, wherein the component is a part of a turbine.

22. A method according to claim 21, wherein the part of a turbine is a turbine blade.
